(19) United States
(12) Patent Application Publication
(10) Pub. No.: US 2022/0225529 A1
(43) Pub. Date: Jul. 14, 2022

(54) POWER ELECTRONICS SYSTEM WITH BUSBARS OF HOLLOW DESIGN FOR DIRECT CAPACITOR COOLING; AND ELECTRIC MOTOR

(71) Applicant: Schaeffler Technologies AG & Co. KG, Herzogenaurach (DE)

(72) Inventors: Nicolai Gramann, Renchen (DE); Christian Nolte, Haßfurt (DE); Matthias Gramann, Renchen (DE); Johannes Herrmann, Achern (DE); Eduard Enderle, Gengenbach (DE)

(73) Assignee: Schaeffler Technologies AG & Co. KG, Herzogenaurach (DE)

(21) Appl. No.: 17/607,487

(22) PCT Filed: Mar. 30, 2020
(86) PCT No.: PCT/DE2020/100259

§ 371 Date: Oct. 29, 2021

(30) Foreign Application Priority Data
Apr. 30, 2019 (DE) 10 2019 111 111.0

(51) Int. Cl. H05K 7/20; H01G 2/08; H02K 9/00

(52) U.S. Cl. CPC H05K 7/2089; H02K 9/00; H01G 2/08

(57) ABSTRACT

A power electronics system for an electric motor of a motor vehicle drive includes a first busbar, a second busbar which is electrically insulated relative to the first busbar, and at least one capacitor. The at least one capacitor, by way of its first electrode, makes contact with a plate-like receiving region of the first busbar and, by way of its second electrode, makes contact with a plate-like receiving region of the second busbar. At least one of the two busbars is of hollow design, with direct formation of a cooling duct.

### CROSS-REFERENCE TO RELATED APPLICATIONS

This application is the U.S. National Phase of PCT Appin. No. PCT/DE2020/100259 filed Mar. 30, 2020, which claims priority to DE 102019111111.0 filed Apr. 30, 2019, the entire disclosures of which are incorporated by reference herein.

### TECHNICAL FIELD

The disclosure relates to a power electronics system for an electric motor of a motor vehicle drive, i.e., a drive train of a motor vehicle, such as a car, truck, bus or other utility vehicle, comprising a first busbar, a second busbar electrically insulated relative to the first busbar and at least one capacitor, wherein the at least one capacitor, by way of its first electrode, makes contact with a plate-like receiving region of the first busbar and, by way of its second busbar, makes contact with a plate-like receiving region of the second busbar. The disclosure also relates to an electric motor, which is preferably used as the drive engine of a drive train of a purely electrically or hybrid-powered motor vehicle, comprising this power electronics system.

### BACKGROUND

Generic power electronics systems are already sufficiently known in the prior art. In this respect, DE 10 2016 218 151 A1 discloses an integrated electronics assembly kit comprising at least one busbar, which is fixed to a cooling component via an electrical insulation layer.

Further prior art is known from DE 10 2016 219 213 A1. A power electronics system is disclosed herein, wherein a cooling device has at least one heat tube that absorbs part of an amount of waste heat.

Thus, in principle, different versions of power electronics systems are known which contribute to cooling the built-in components as efficiently as possible and thus increasing the power density. While in principle it would be possible to increase the number of capacitors or to dimension the capacitors larger in order to transmit greater power, this would in turn involve considerable disadvantages in terms of installation space.

Another disadvantage of the designs known from the prior art is that the power electronics systems realized to implement the highest possible power density often have a relatively complex structure. In addition, the feasibility of the power electronics system is often linked to a certain minimum size.

### SUMMARY

Therefore, the object of the present disclosure is to eliminate the disadvantages known from the prior art and, in particular, to implement a power electronics system with a further increased power density, wherein the power electronics system comprises the simplest possible structure and a small number of components.

According to the disclosure, this is achieved by the fact that at least one of the two busbars is hollow in design, with the direct formation of a cooling duct.

By designing at least one busbar as a waveguide busbar, the busbar that is already present is used directly as part of a cooling device without significantly increasing the total number of components or the installation space requirement. The power density of the corresponding power electronics system can thus be significantly increased once again.

Further advantageous embodiments are claimed and explained in more detail below.

It is therefore also advantageous if the at least one hollow busbar forms a hollow wall, which is sealed/closed off relative to its surroundings at its lateral end edges. As a result, the busbar is implemented with the largest possible hollow space.

In this context, it is additionally advantageous if the first busbar forms a first cooling duct which is connected to an inlet connection of the first busbar that can be connected to a coolant inlet. As a result, a cooling duct of the first busbar can be further connected to a coolant supply in a particularly simple manner during operation.

If both busbars, i.e., both the first busbar and the second busbar, are (each) hollow in design with the formation of a cooling duct, the cooling capacity of the cooling device is further improved during operation.

It is therefore additionally advantageous if the second busbar has a second cooling duct which is connected to a return connection of the second busbar that can be connected to a coolant return. As a result, a connection on the return side of a coolant supply is also implemented in a particularly simple manner.

Furthermore, it is advantageous if the cooling ducts are directly connected to one another. In this context, it has been found to be particularly advantageous if the cooling ducts of the two busbars are hydraulically connected to one another via a connecting element.

In this respect, it is also advantageous if the connecting element is designed as a tube. The tube is then connected to the first cooling duct at its first end and connected to the second cooling duct at its second end. This keeps the design particularly simple. The connecting element is preferably implemented as an electrical insulator.

With regard to the positioning of the connecting element, in order to generate an effective coolant circuit during operation, it is advantageous if the connecting element is received on an end region of the respective busbar facing away from the return connection and/or the inlet connection. Expressed in other words, this means that the connecting element, viewed in the axial direction of the busbar, is arranged on an axial side of the receiving region facing away from the return connection and the inlet connection.

For the connection of the power electronics system, it is advantageous if both busbars form a plurality of mounting regions that are arranged/protruding towards a common side of the at least one capacitor. The mounting regions are preferably implemented as tabs. It is also advantageous in this context if both the (first) mounting regions of the first busbar and the (second) mounting regions of the second busbar lie in a common mounting plane.

The disclosure further relates to an electric motor for a motor vehicle, comprising a power electronics system according to the disclosure according to at least one of the previously described embodiments. The power electronics system is used in a typical manner to control the electric motor, i.e., to forward electrical energy supplied to the stator of the electric motor or generated by said stator.

Expressed in other words, according to the disclosure, a direct active capacitor cooling with a plurality of waveguide busbars (busbars) is realized. The waveguides (busbars) are used as busbars that make contact with a plurality of capacitors. A non-conductive cooling fluid (liquid) flows through the bus bars to dissipate heat from critical regions. Usually, the majority of losses are caused by a high current density within the busbars. By cooling the busbars, these losses are efficiently avoided and the capacitors can be made smaller.

### BRIEF DESCRIPTION OF THE DRAWINGS

In the following, the disclosure is now explained in more detail with reference to figures.

In the figures:

FIG. 1 shows a longitudinal sectional view of a power electronics system according to the disclosure according to a preferred exemplary embodiment, wherein the formation of two busbars which couple a plurality of capacitors to one another can be clearly seen,

FIG. 2 shows a perspective full view of the power electronics system according to FIG. 1, and

FIG. 3 shows a simplified representation of a possible design of an electric motor comprising the power electronics system according to FIGS. 1 and 2.

The figures are only schematic in nature and serve only for understanding the disclosure. The same elements are provided with the same reference symbols.

### DETAILED DESCRIPTION

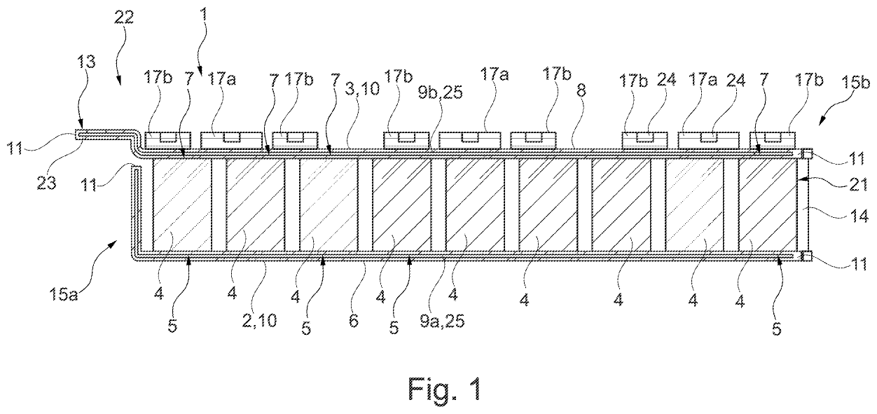

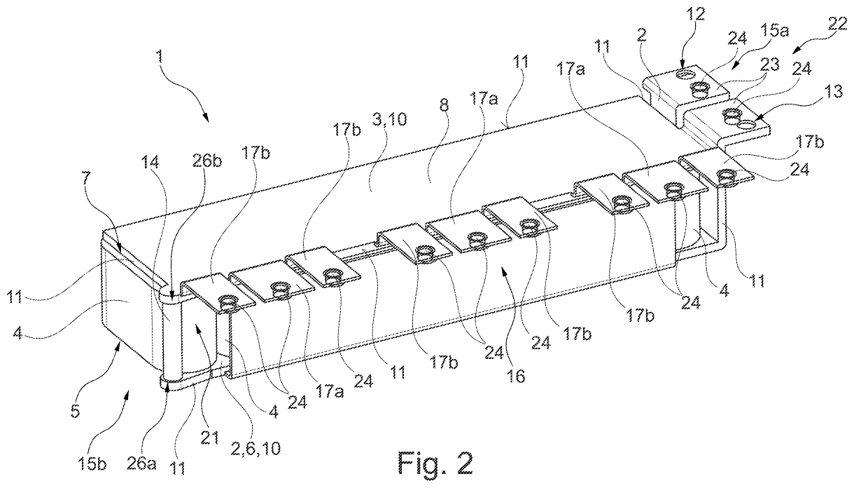

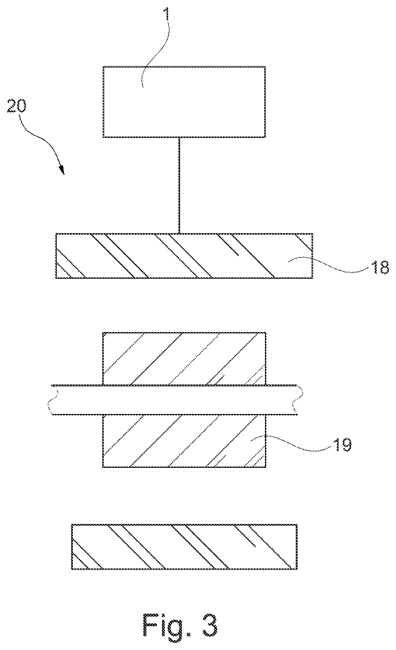

Referring to FIGS. 1 and 2, an embodiment of the power electronics system 1 according to the disclosure can be seen in detail. The power electronics system 1 is illustrated in these representations on the part of a capacitor unit and thus is alternatively also referred to as a capacitor unit. During operation, the power electronics system 1 is used to control an electric motor 20, as shown schematically in connection with FIG. 3. The electric motor 20 comprises, for example, a stator 18 that is fixed to the housing and a rotor 19 that is rotatably arranged relative to the stator 18. In its preferred area of application, the electric motor 20 is used as a drive engine of a hybrid or purely electrically driven motor vehicle. Thus, when in operation, the electric motor 20 is used in a drive train of the corresponding motor vehicle. The power electronics system 1 is typically electrically coupled to the stator 18 to control the electric motor 20. As a result, electrical energy can, in principle, be supplied to the stator 18 by the power electronics system 1 or be received by the stator 18.

In FIGS. 1 and 2, the essential structure of a power electronics system 1 according to the disclosure can be seen. The power electronics system 1 has two busbars 2 and 3 that are electrically insulated relative to one another. A first busbar 2, has a first plate-like receiving region 6, as can be clearly seen in FIG. 2. A second busbar 3 has a second plate-like receiving region 8. The two receiving regions 6, 8 are aligned parallel to one another. The two receiving regions 6, 8 are essentially rectangular. The two receiving regions 6, 8 are also arranged at a distance from one another, so that a receiving space 21 is formed between the two receiving regions 6, 8. A plurality of capacitors 4 are arranged in the receiving space 21. Alternatively, these capacitors 4 can also each be implemented as a capacitor winding and thus form a common capacitor 4.

The respective capacitor 4 has two electrodes 5, 7. A first electrode 5 of the capacitor 4 makes contact with the first receiving region 6 and thus the first busbar 2. A second electrode 7 of the capacitor 4 makes contact with the second receiving region 8 and thus the second busbar 3. The capacitors 4 are firmly fixed between the two busbars 2, 3 and attached to the respective busbar 2, 3 by their electrodes 5, 7.

According to the disclosure, each busbar 2, 3 forms a hollow wall 10, as can be clearly seen in FIG. 1. This means that the respective busbar 2, 3 is designed to be hollow. An inner hollow space 25 of the respective busbar 2, 3 forms a cooling duct 9a, 9b. The first busbar 2 therefore forms a first cooling duct 9a of a cooling device 22. The second busbar 3 therefore forms a second cooling duct 9b of the cooling device 22. In FIG. 1 it can also be clearly seen that the receiving regions 6, 8 of the busbars 2, 3 are hollow in design, so that the respective cooling duct 9a, 9b extends so long that it protrudes beyond all the capacitors 4 of the power electronics system 1 in a longitudinal direction of the busbar 2, 3. The first cooling duct 9a protrudes beyond all of the capacitors 4 on the part of their first electrodes 5; the second cooling duct 9b protrudes beyond all of the capacitors 4 on the part of their second electrodes 7.

As can be seen in connection with FIG. 2, each busbar 2, 3 is provided with a connection 12, 13 via which it is connected to a coolant supply of the cooling device 22 during operation. While the first cooling duct 9a is provided with an inlet connection 12 which is formed directly on the first busbar 2 (in the form of a borehole), the second busbar 3 has a return connection 13, wherein the return connection 13 is connected to the second cooling duct 9b, which is formed directly on the second busbar 3 (in the form of a borehole).

The inlet connection 12 and the return connection 13 are also attached in a hollow protrusion region 23 of the respective busbars 2, 3 which form the cooling duct 9a, 9b. Viewed in the longitudinal direction of the busbars 2, 3, the inlet connection 12 and the return connection 13 are arranged to the side of the capacitors 4 on an axial end of the respective busbars 2, 3. In particular, both the inlet and return connections 12, 13 are arranged towards a common first axial end region 15a of the busbars 2, 3.

The two cooling ducts 9a, 9b are hydraulically connected to one another at a second end region 15b of the busbars 2, 3 axially facing away from the first end region 15a. For this purpose, a connecting element 14 is present which is implemented in an electrically insulating manner. The connecting element 14 is implemented as a tube in this embodiment. The connecting element 14 is connected with its first end 26a to the first cooling duct 9a; with its second end 26b, the connecting element 14 is connected to the second cooling duct 9b. It is thus possible to generate a coolant circuit during operation, wherein the coolant, preferably an electrically non-conductive fluid (preferably liquid), initially enters the first cooling duct 9a of the first busbar 2 through the inlet connection 12, flows axially through the first busbar 2 and flows over the region of the connecting element 14 into the second cooling duct 9b of the second busbar 3. The coolant then flows through the second cooling duct 9b of the second busbar 3 to the return connection 13.

As can also be seen in connection with FIGS. 1 and 2, the busbars 2, 3 each have mounting regions 17a, 17b by means of which, during operation, they are connected to a housing, which is not shown here for the sake of clarity. The first busbar 2 has a plurality of tab-shaped first mounting regions 17a arranged at a distance from one another in the longitudinal direction; the second busbar 3 has a plurality of tab-shaped second mounting regions 17b arranged at a distance from one another in the longitudinal direction. It can be seen here that the mounting regions 17a and 17b are located in a common mounting plane. The mounting regions 17a and 17b are also arranged on a common side. The mounting regions 17a, 17b are equipped with mounting holes 24 in the form of through holes for receiving a mounting means.

Furthermore, it can be seen that mounting holes 24 are also made in the protrusion regions 23 of the first busbar 2 and the second busbar 3, by means of which the protrusion region 23 can also be used as a mounting region. A mounting hole 24 of the protrusion region 23 of the first busbar 2 is arranged at a distance from the inlet connection 12 and the first cooling duct 9a. A mounting hole 24 of the protrusion region 23 of the second busbar 3 is arranged at a distance from the return connection 13 and the second cooling duct 9b.

In other words, with this inventive solution, waveguides are used as busbars 2, 3. A non-conductive cooling liquid flows through this, which transports the heat generated from the critical areas. In FIG. 1, the interior of a capacitor (capacitor unit 1) can be seen. This consists of two busbars (DC busbar plus (first busbar 2); DC busbar minus (second busbar 3)), as well as the non-conductive coolant transfer (connecting element 14). The flat windings (capacitors 4) are not discussed in detail. As can be seen in FIG. 2, the busbars 2, 3 are hollow. A non-conductive cooling liquid flows inside the busbars 2, 3. The coolant flows in via the coolant inlet 12, flows through the DC busbar plus 2 and then flows through the coolant transfer 14 into the DC busbar minus 3. The liquid flows back to the cooler through the coolant outlet 13. The majority of the losses occur in the busbars 2, 3 due to the high current density. In this concept, the losses are “cooled off” exactly where they arise. This efficient cooling makes it possible to design the condenser 4 to be smaller. This has an effect on the installation space of the entire power electronics system 1, since there the capacitor 4 represents the largest component in terms of volume. The efficient cooling therefore enables a higher power density.

### LIST OF REFERENCE NUMBERS

1 Power electronics system

2 First busbar

3 Second busbar

4 Capacitor

5 First electrode

6 First receiving region

7 Second electrode

8 Second receiving region

9a First cooling duct

9b Second cooling duct

10 Hollow wall

11 End edge

12 Inlet connection

13 Return connection

14 Connecting element

15a First end region

15b Second end region

16 Side

17a First mounting region

17b Second mounting region

18 Stator

19 Rotor

20 Electric motor

21 Receiving space

22 Cooling device

23 Protrusion region

24 Mounting hole

25 Hollow space

26a First end

26b Second end

1. A power electronics system for an electric motor of a motor vehicle drive, comprising: a first busbar, a second busbar that is electrically insulated relative to the first busbar and at least one capacitor, the at least one capacitor, by way of its first electrode, making contact with a plate-like receiving region of the first busbar and, by way of its second electrode, making contact with a plate-like receiving region of the second busbar wherein at least one of the first busbar or the second busbar is of hollow design, with direct formation of a cooling duct.

2. The power electronics system according to claim 1, wherein the respective first or second busbar of hollow design forms a hollow wall that is sealed relative to surroundings at its lateral end edges.

3. The power electronics system according to claim 1, wherein the first busbar forms a first cooling duct that is connected to an inlet connection of the first busbar that can be connected to a coolant inlet.

4. The power electronics system according claim 1, wherein the first and the second busbars are of hollow design, with formation of a cooling duct.

5. The power electronics system according to claim 3, wherein the second busbar has a second cooling duct that is connected to a return connection of the second busbar that can be connected to a coolant return.

6. The power electronics system according to claim 5, wherein the first and the second cooling ducts of the first and the second busbars are hydraulically connected to one another via a connecting element.

7. The power electronics system according to claim 6, wherein the connecting element is designed as a tube.

8. The power electronics system according to claim 6, wherein the connecting element is received on an end region of the first and the second busbars facing away from the return connection the inlet connection.

9. The power electronics system according to claim 1, wherein the first and the second busbars form a plurality of mounting regions arranged towards a common side of the at least one capacitor.

10. An electric motor for a drive train of a motor vehicle, having a power electronics system according to claim 1.
